(19) United States
(12) Patent Application Publication
(10) Pub. No.: US 2026/0255986 A1
(43) Pub. Date: Aug. 27, 2026

(54) CONDUCTIVE PATH FOR A LEAD-FRAME CURRENT SENSOR

(71) Applicant: STMicroelectronics International N.V., Geneva (CH)

(72) Inventors: Mark Andrew SHAW, Milan (IT); Marco DEL SARTO, Monza (IT); Dario PACI, Vittuone (IT); Andrea RATTI, Agrate Brianza (IT)

(21) Appl. No.: 19/064,138

(22) Filed: Feb. 26, 2025

(51) Int. Cl. H10W 70/40; G01R 15/20; G01R 19/00; H10W 74/10; H10W 90/00

(52) U.S. Cl. CPC H10W 70/435; G01R 15/207; G01R 19/0092; H10W 70/424; G01R 15/202; H10W 74/10; H10W 90/756

(57) ABSTRACT

An example lead-frame package, a lead-frame current sensor, and a method for determining a signal current of an electrical signal at a lead-frame current sensor are provided. An example lead-frame package includes an interface surface and a conductive path. The conductive path configured to receive an electrical signal with a signal current. The conductive path comprising an input pad, output pad, and bridge portion. The input pad forming a first portion of the interface surface. The output pad forming a second portion of the interface surface, wherein a separation gap is defined between the input pad and the output pad. The bridge portion electrically connecting the input pad to the output pad, wherein the bridge portion is removed from the interface surface. The separation gap is tapered such that the separation gap linearly converges toward the bridge portion electrically connecting the input pad and the output pad.

### TECHNOLOGICAL FIELD

Embodiments of the present disclosure relate generally to the conductive path for an electrical signal in a lead-frame current sensor, and more particularly, to an input pad, output pad, and bridge portion configuration of a conductive path on a lead-frame current sensor.

### BACKGROUND

Many electronic systems utilize printed circuit boards (PCBs) to support and connect the various electrical components of the electrical system. For example, a PCB may include a rigid structure with a plurality of mount regions configured to receive various electrical components. The PCB may further include conductive traces or paths to enable electrical connections between the various electrical components. A PCB may commonly receive surface-mounted and/or socketed electrical components, including various integrated circuits (ICs). Some surface-mounted packages, for example lead-frame packages, include ICs configured to determine the current flow through a conductive trace.

Applicant has identified many technical challenges and difficulties associated with determining current flow through a conductive trace at a lead-frame package. Through applied effort, ingenuity, and innovation, Applicant has solved problems related to determining current flow at a lead-frame package by developing solutions embodied in the present disclosure, which are described in detail below.

### BRIEF SUMMARY

Various embodiments are directed to an example lead-frame package, a lead-frame current sensor, and a method for determining a signal current associated with an electrical signal at a lead-frame current sensor.

An example lead-frame package is provided. The example lead-frame package includes an interface surface and a conductive path. The conductive path configured to receive an electrical signal comprising a signal current. The conductive path comprising an input pad, an output pad, and a bridge portion. The input pad forming at least a first portion of the interface surface. The output pad forming at least a second portion of the interface surface, wherein a separation gap is defined between the input pad and the output pad. The bridge portion electrically connecting the input pad to the output pad, wherein the bridge portion is removed from the interface surface. The separation gap is tapered such that the separation gap linearly converges toward the bridge portion electrically connecting the input pad and the output pad.

In some embodiments, the lead-frame package further comprises: a lead, wherein a portion of the lead is exposed at the interface surface proximate a lead package side of the lead-frame package.

In some embodiments, the input pad further comprises a lead edge and a pad edge. The lead edge comprising a lead edge length proximate the lead. The pad edge comprising a pad edge length opposite the lead edge.

In some embodiments, the lead edge length is less than the pad edge length.

In some embodiments, the pad edge is closer to the bridge portion than the lead edge.

In some embodiments, a lead-pad distance defining a distance between the lead and the lead edge of the input pad is greater than a minimum lead-pad distance.

In some embodiments, the minimum lead-pad distance is 3.5 millimeters.

In some embodiments, the input pad further comprises a gap edge and a first converging edge. The gap edge adjacent to the separation gap defined between the input pad and the output pad. The first converging edge adjacent to the gap edge, wherein the first converging edge comprises a first converging edge angle relative to the gap edge. In some embodiments, the first converging edge angle is greater than four degrees and less than forty-five degrees.

In some embodiments, the lead-frame package further comprises a second converging edge adjacent to the gap edge opposite the first converging edge, wherein the second converging edge comprises a second converging edge angle relative to the gap edge. In some embodiments, the second converging edge angle is greater than four degrees and less than forty-five degrees.

In some embodiments, the lead-frame package includes a first input pad layer and a second input pad layer. The first input pad layer forming the first portion of the interface surface. Wherein a second cross-sectional area of the second input pad layer is greater than a first cross-sectional area of the first input pad layer.

In some embodiments, the bridge portion further comprises a bridge portion length, wherein the separation gap proximate the bridge portion at the first input pad layer is equivalent to the bridge portion length.

In some embodiments, the bridge portion length is greater than 0.5 millimeters and less than 0.6 millimeters.

In some embodiments, the input pad comprises an input rectangular portion and an input trapezoidal portion, wherein the input trapezoidal portion defines the separation gap.

In some embodiments, the output pad comprises an output rectangular portion; and an output trapezoidal portion; wherein the output trapezoidal portion defines the defines the separation gap.

In some embodiments, the input pad comprises an input pad width, wherein the input pad width is greater than 2.75 millimeters.

In some embodiments, the input pad comprises an input pad height, wherein the input pad height is greater than 2 millimeters.

In some embodiments, the lead-frame package is configured to measure the signal current at an integrated circuit (IC) die.

A lead-frame current sensor is further provided. In some embodiments, the lead-frame current sensor comprises an interface surface, a conductive path, and an IC sensor. The conductive path configured to receive an electrical signal comprising a signal current. The conductive path comprising an input pad, an output pad, and a bridge portion. The input pad forming at least a first portion of the interface surface. The output pad forming at least a second portion of the interface surface, wherein a separation gap is defined between the input pad and the output pad; and the bridge portion electrically connecting the input pad to the output pad, wherein the bridge portion is removed from the interface surface. The separation gap is tapered such that the separation gap linearly converges toward the bridge portion electrically connecting the input pad and the output pad. The integrated circuit (IC) die positioned proximate the bridge portion of the conductive path, and separated from the bridge portion of the conductive path by an electrically insulating layer.

In some embodiments, the input pad comprises an input rectangular portion, and an input trapezoidal portion. In some embodiments, the output pad comprises an output rectangular portion, and an output trapezoidal portion. Wherein the input trapezoidal portion and the output trapezoidal portion define the separation gap.

A method for determining a signal current associated with an electrical signal, the method comprising: providing a lead-frame current sensor comprising: an interface surface; a conductive path comprising: an input pad forming at least a first portion of the interface surface; an output pad forming at least a second portion of the interface surface, wherein a separation gap is defined between the input pad and the output pad; and a bridge portion electrically connecting the input pad to the output pad, wherein the bridge portion is removed from the interface surface, wherein the separation gap is tapered such that the separation gap linearly converges toward the bridge portion electrically connecting the input pad and the output pad; and an integrated circuit (IC) die positioned proximate the bridge portion of the conductive path, and separated from the bridge portion of the conductive path by an electrically insulating layer. The method further comprising receiving the electrical signal at the input pad of the conductive path, the electrical signal comprising the signal current; transmitting the electrical signal through the bridge portion of the conductive path; and determining the signal current based on a magnetic field generated by the electrical signal passing through the bridge portion.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates an example lead-frame current sensor comprising a conductive path in accordance with an example embodiment of the present disclosure.

FIG. 2 illustrates a top view of an example conductive path comprising a converging separation gap in accordance with an example embodiment of the present disclosure.

FIG. 3 illustrates a bottom view of an example conductive path comprising a converging separation gap in accordance with an example embodiment of the present disclosure.

FIG. 4 illustrates a side view of an example conductive path in accordance with an example embodiment of the present disclosure.

FIG. 5 illustrates a top view of an example embodiment of a conductive path comprising a converging separation gap in accordance with an example embodiment of the present disclosure.

FIG. 6 illustrates a bottom view of an example embodiment of a conductive path comprising an input pad, an output pad, and a bridge portion in accordance with an example embodiment of the present disclosure.

FIG. 7 illustrates a bottom view of an example embodiment of a lead-frame current sensor in accordance with an example embodiment of the present disclosure.

FIG. 8 depicts a flow chart of an example process for a signal current associated with an electrical signal in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with defining a conductive path on a lead-frame package configured to determine an electrical property of an electrical signal transmitted through the lead-frame package. As understood by those of skill in the field to which the present disclosure pertains, there are numerous example lead-frame packages that utilize a conductive path to determine one or more electrical properties of an electrical signal received at the lead-frame package.

For example, many electronic systems utilize printed circuit boards (PCBs) to support and connect the various electrical components of the electrical system. A PCB may include a rigid structure with a plurality of mount regions configured to receive various electrical components. The PCB may further include conductive traces or paths to enable electrical connections between the various electrical components. Each conductive trace or path may carry an electrical signal. A PCB may commonly receive surface-mounted and/or socketed electrical components, including various integrated circuits (ICs) interconnected with the conductive traces.

One example structure for connecting an IC to a PCB is a lead-frame package. A lead-frame package is a surface-mount technology providing structural support for an IC, protection from environmental factors, and an electrical connection between the PCB and the IC without through holes. Conductive surfaces (leads) at the bottom surface of the lead-frame package are coupled with conductive surfaces on the surface of the PCB. The lead-frame package protects the electrical components and electrical connections of the IC from environmental factors ensuring reliability of the electrical system even in extreme conditions. Example lead-frame packages include quad-flat packages (QFP), quad-flat no-leads (QFN) packages, and quad-flat no-leads multi-row (QFNmr) packages.

Some lead-frame packages include ICs (e.g., IC die) configured to determine a current flow of an electrical signal transmitted through a conductive trace. A conductive trace may be electrically coupled to a conductive path of the lead-frame package. The lead-frame package may be configured to transmit the current through a narrow trace (e.g., bridge portion) of the lead-frame package proximate the IC die. The IC die may be configured to sense the magnetic field (e.g., using a Hall sensor) to determine a current of the electrical signal based on the magnetic field. For accurate measurements, the current is concentrated into a narrow conductive path (e.g., bridge portion) directly under the IC die. In this way, the geometry of the conductive path through the lead-frame package is optimized to enhance the magnetic field generated near the IC die.

However, in some embodiments, optimizing the structure of the lead-frame results in narrow gaps and channels. Narrow gaps, channels, and other tight areas may be difficult to fill with molding material during the manufacturing process. Lack of molding material in the various gaps and channels may lead to inadequate protection of the various components of the lead-frame package. In addition, lack of molding in the various gaps and channels may lead to inconsistent or inaccurate electrical components within the lead-frame package. Such inconsistent or inaccurate electrical components may generate inaccurate and/or undesirable results. In addition, the conductive path of some example lead-frame packages may be susceptible to hot spots or focused areas of high temperature.

The various example embodiments described herein utilize various techniques to improve the performance of a lead-frame package configured to determine one or more electrical properties of an electrical signal transmitted through a conductive path in the lead-frame package. For example, in some embodiments, a lead-frame package may comprise a conductive path comprising an input pad forming at least a first portion of an interface surface of the lead-frame package and configured to receive an electrical signal; an output pad forming at least a second portion of the interface surface and configured to transmit the electrical signal into a conductive trace of the connected circuit board; and a bridge portion electrically connecting the input pad to the output pad and configured to transmit the electrical signal from the input pad to the output pad. In some embodiments, the bridge portion may be positioned proximate an IC die configured to determine an electrical property of the electrical signal. For example, the IC die may utilize the Hall Effect to determine the signal current of the electrical signal transmitted through the bridge portion of the conductive path.

For reliable and efficient operation, the electrical components of a lead-frame package may be surrounded by a molding material. For example, molding material may provide mechanical protection to the lead-frame and die; electrical insulation, for example, to prevent short circuits and unwanted electrical interference; and environmental protection, for example, protection from moisture, gas, dust, chemicals, and so on. In some embodiments of the present disclosure, a converging separation gap between the input pad and the output pad is formed. A separation gap is a space or gap between the input pad and output pad, separating the input pad from the output pad of the conductive path. A converging separation gap comprises a width at the periphery of the input pad and output pad that is wider relative to a width closer to the bridge portion connecting the input pad and output pad. A converging separation pad enables molding material to more easily penetrate all of the gaps within the lead-frame package. For example, filling the converging separation gap, including the space under the bridge portion of the conductive path.

In addition, in some embodiments, a lead-frame package in accordance with an example embodiment of the present disclosure may include a conductive path with two or more layers. For example, the input and output pads may comprise a first layer forming at least a portion of the interface surface of the lead-frame package. However, the bridge portion of the conductive path may be removed from the interface surface. In other words, the bridge portion is not co-planar with the interface surface formed at least in part by the first layer of the input pad and the first layer of the output pad. In some embodiments, the bridge portion may electrically connect with a second layer of the input pad and output pad, elevated from the interface surface such that a space is defined between the bridge portion of the conductive path and the interface surface of the lead-frame package. During the manufacturing process, the converging separation gap enables molding material to more easily fill such a space.

As a result of the herein described example embodiments and in some examples, the accuracy and reliability of a lead-frame package configured to receive an electrical signal at a conductive path may be greatly improved. For example, the conductive path may be configured such that a molding material may penetrate each of the gaps of the lead-frame package, particularly, the separation gap between the input pad and the output pad of the conductive path.

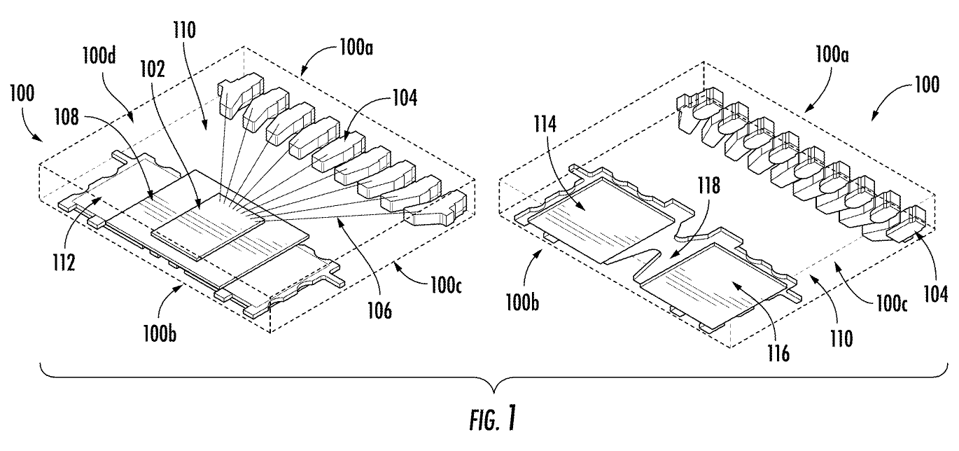

Referring now to FIG. 1, a top view and bottom view of an example lead-frame package 100 is provided. As depicted in FIG. 1, the example lead-frame package 100 comprises a molding material 110 defining in part the outer bounds of the lead-frame package 100, including a lead package side 100a proximate a plurality of leads 104, an IC package side 100b proximate an IC die 102, and an interface surface 100c configured to interface with a system circuit board (e.g., a PCB). As further depicted in FIG. 1, the lead-frame package 100 includes a conductive path 112 (e.g., lead frame) comprising an input pad 114 and an output pad 116. The conductive path 112 is positioned proximate the IC die 102 and separated from the IC die 102 by an electrically insulating layer 108.

As depicted in FIG. 1, the example lead-frame package 100 includes an IC die 102. An IC die 102 (e.g., semiconductor IC) is any block of semiconductor material utilizing circuitry and/or electrical components to perform one or more functions. An IC die 102 may include a processor, reconfigurable fabric, passive electrical components, active electrical components, memory, communications circuitry, and/or any other electrical components necessary to perform the functionality of the IC die 102.

An IC die 102 is further configured to receive and/or generate one or more electrical signals. The one or more electrical signals are transmitted between the IC die 102 and an electrical system through the one or more leads 104. As depicted in FIG. 1, the one or more leads 104 provide an external conductive surface at the interface surface 100c of the lead-frame package 100 to electrically interface with the IC die 102.

As further depicted in FIG. 1, each lead 104 is electrically coupled to the IC die 102 with a conductive bond wire 106. A conductive bond wire 106 is any electrically conductive material forming a conductive path from a lead 104 to an electrical input and/or output of the IC die 102. The conductive bond wire 106 facilitates the transmission of electrical signals between the IC die 102 and the leads 104, providing an electrical connection to an external electrical system. Conductive bond wires 106 may comprise aluminum, copper, silver, gold, or other similar conductive materials. In some embodiments, a conductive bond wire 106 may be attached using a ball bonding technique, or a wedge bonding technique.

In some embodiments, for example in an instance in which the lead-frame package 100 comprises a lead-frame current sensor, the IC die 102 may be configured to determine electrical properties of an electrical signal passing through the conductive path 112. In one example embodiment, the IC die 102 is configured to determine the signal current associated with the electrical signal passing through the conductive path 112 proximate the IC die 102. In such an embodiment, the IC die 102 is configured to measure one or more electromagnetic properties of the electrical signal while electrically insulated from the conductive path 112 by the electrically insulating layer 108. For example, the IC die 102 may utilize the Hall effect to determine the signal current in the electrical signal passing through the conductive path 112 based on changes in the magnetic field detected at the IC die 102.

As further depicted in FIG. 1, the example lead-frame package 100 includes an electrically insulating layer 108 between the IC die 102 and the conductive path 112. The electrically insulating layer 108 comprises an insulating dielectric, compound, tape, or other material that is positioned between the IC die 102 and the conductive path 112. The electrically insulating layer 108 provides an electrically insulating divider between the IC die 102 and the conductive path 112. Insulating materials comprising the electrically insulating layer 108 may include any non-conductive material, for example, a molding substance, an epoxy, a resin, a `polymer plastic, a tape, or other similar material. The electrically insulating layer 108 enables a magnetic field generated by the electrical signal passing through the conductive path 112 to be detected at the IC die 102 without altering the electrical properties of the electrical signal.

As further depicted in FIG. 1, the example lead-frame package 100 includes a conductive path 112 comprising an input pad 114, and output pad 116, and a bridge portion 118 electrically connecting the input pad 114 and the output pad 116.

As depicted in FIG. 1, the input pad 114 of the conductive path 112 forms at least a portion of the interface surface 100c of the lead-frame package 100. As such, the input pad 114 may interface with a conductive surface of the system circuit board configured to receive a lead-frame package 100.

The input pad 114 is configured to receive an electrical signal. An electrical signal may comprise any flow of electric charge or voltage that conveys information, provides power, or otherwise transmit electric charge. In some embodiments, an electrical system may benefit from measuring, tracking, and/or monitoring one or more electrical properties of the electrical signal. For example, in one embodiment, a plurality of electrical signals may be used to power a monitor in the electrical system. In such an embodiment, the power provided to the motor may be directly proportional to the electrical properties of the electrical signals provided to the motor, for example, the signal current of the electrical signal. As such, the electrical system (e.g., system circuit board) may provide an interface with the one or more conductive traces receiving the electrical signal. By aligning the input pad 114 of the conductive path 112 with the interface to the one or more conductive traces, the electrical signal may be transmitted through the conductive path 112 of the lead-frame package 100 and the electrical properties of the electrical signal may be measured by the IC die 102.

As further depicted in FIG. 1, the output pad 116 of the conductive path 112 forms at least a portion of the interface surface 100c of the lead-frame package 100. As such, the output pad 116 may interface with a conductive surface of the system circuit board configured to receive a lead-frame package 100. The output pad 116 is configured to transmit the electrical signal back in to the system circuit board of the electrical system. Thus, the electrical signal is received at the input pad 114 of the conductive path 112, is transmitted through the bridge portion 118 of the conductive path 112, and is transmitted back to the electrical system through the output pad 116.

The electrical system (e.g., system circuit board) may provide an interface with one or more conductive traces carrying the electrical signal through the system circuit board. By aligning the output pad 116 of the conductive path 112 with the interface to one or more conductive traces, in conjunction with the input pad 114, the electrical signal may be transmitted through the conductive path 112 of the lead-frame package 100 and the electrical properties of the electrical signal may be measured by the IC die 102.

As further depicted in FIG. 1, the conductive path 112 comprises a bridge portion 118. As depicted in FIG. 1, the bridge portion 118 comprises a conductive structure electrically interconnecting the input pad 114 and the output pad 116 wherein the bridge portion 118 is removed from, or set back from the interface surface 100c. Thus, the bridge portion 118 is not exposed at the interface surface 100c of the lead-frame package 100. The bridge portion 118 comprises a conductive path having a smaller cross-sectional area compared to the cross-section area of the input pad 114 and the output pad 116. The bridge portion 118 of the conductive path 112 is designed to concentrate the current flow of the electrical signal in a small area. By transmitting the flow of current through the bridge portion 118 having a smaller cross-sectional area, the flow of current may be brought in closer proximity to the sensing elements of the IC die 102. By isolating and narrowing the bridge portion 118 of the conductive path 112, the current passing through the conductive path 112 may be concentrated near the active area of the IC die 102. Concentrating the current near the active area may generate more accurate measurements of the electromagnetic properties of the electrical signal in the conductive path 112.

As further depicted in FIG. 1, the example lead-frame package 100 is defined by molding material 110. The molding material 110 comprises any non-conductive material configured to protect an IC die 102, bond wires 106, and other electrical components within the lead-frame package 100 from a surrounding environment. For example, in some embodiments, an IC die 102 may utilized in an electrical system in a harsh environment (e.g., high temperatures, low temperatures, exposed to dirt, water, dust, sand, etc.). For example, a lead-frame package 100 may be utilized to protect an IC die 102 in a portion of an automobile (e.g., engine, chassis, driveline, etc.). As depicted in FIG. 1, the molding material 110 is formed to define an interface surface 100c in addition to at least a lead package side 100a and a IC package side 100b. The molding material 110 further forms the top surface 100d of the lead-frame package 100. The molding material 110 may comprise a resin, polymer plastic, or other insulating material.

As further depicted in FIG. 1, the molding material 110 may be formed, ground, etched, or otherwise configured to expose a portion of the input pad 114 and the output pad 116 of the conductive path 112. Exposing a portion of the input pad 114 and the output pad 116 enable the conductive path 112 to interface with an electrical system (e.g., system circuit board or PCB) and receive an electrical signal for which electrical properties (e.g., current) of the electrical signal may be determined. Importantly, the conductive path 112 is designed such that molding material 110 fills the space between the bridge portion 118 of the conductive path 112 and the interface surface 100c, such that the bridge portion 118 is not exposed at the interface surface 100c.

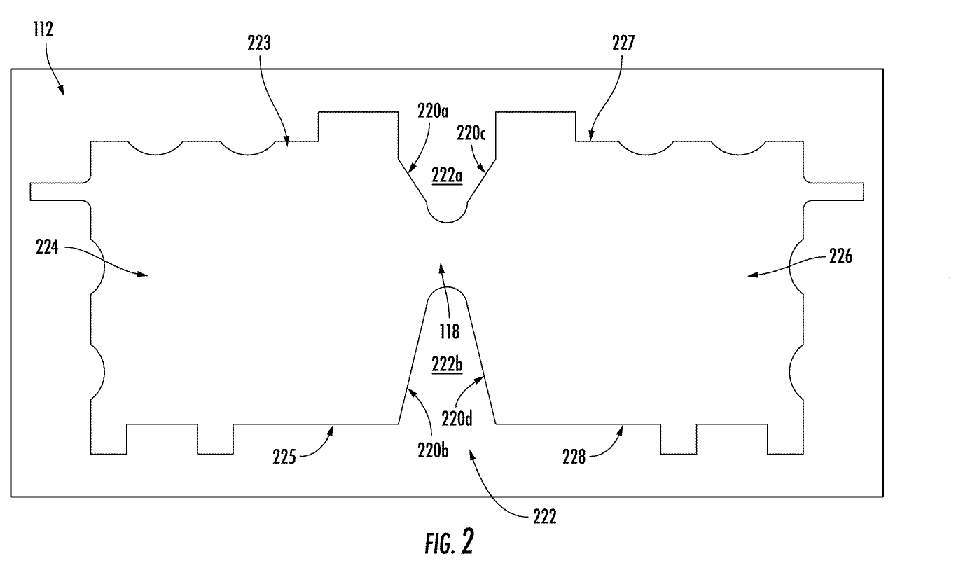

Referring now to FIG. 2, a top view of an example conductive path 112 is depicted. As depicted in FIG. 2, the example conductive path 112 includes an input portion 224 and an output portion 226 connected by a bridge portion 118. The input portion 224 and output portion 226 are separated by and define a separation gap 222. The input portion 224 of the conductive path 112 and the output portion 226 of the conductive path 112 each comprise a set of converging edges 220a, 220b, 220c, 220d forming a converging (e.g., V-shaped) separation gap 222.

As depicted in FIG. 2, the example conductive path 112 includes an input portion 224. Although not depicted in FIG. 2, the input portion 224 comprises an input pad (e.g., input pad 114). Thus, an electrical signal may be received at the input portion 224. In some embodiments, the input portion 224 may comprise a plurality of layers, for example, a first layer forming the input pad, and a second layer co-planar with the bridge portion 118. Thus, the input portion 224 may form a portion of the interface surface of a lead-frame package (e.g., input pad) and electrically connect with the bridge portion 118 which is removed from the interface surface of the lead-frame package.

As further depicted in FIG. 2, the input portion 224 comprises a first converging edge 220a defining a portion of the separation gap 222 between a first edge 223 of the input portion 224 and the bridge portion 118 of the conductive path 112. In addition, the input portion 224 comprises a second converging edge 220b defining a portion of the separation gap 222 between a second edge 225 of the input portion 224 and the bridge portion 118 of the conductive path 112.

As further depicted in FIG. 2, the example conductive path 112 includes an output portion 226. Although not depicted in FIG. 2, the output portion 226 comprises an output pad (e.g., output pad 116). Thus, an electrical signal may be transmitted from the input portion 224, through the bridge portion 118, and out of the output portion 226, for example, back into the electrical system (e.g., system circuit board). In some embodiments, the output portion 226 may comprise a plurality of layers, for example, a first layer forming the output pad, and a second layer co-planar with the bridge portion 118. Thus, the output portion 226 may form a portion of the interface surface of a lead-frame package (e.g., output pad) and electrically connect with the bridge portion 118 which is removed from the interface surface of the lead-frame package.

As further depicted in FIG. 2, the output portion 226 comprises a first converging edge 220c defining a portion of the separation gap 222 between a first edge 227 of the output portion 226 and the bridge portion 118 of the conductive path 112. In addition, the output portion 226 comprises a second converging edge 220d defining a portion of the separation gap 222 between a second edge 228 of the output portion 226 and the bridge portion 118 of the conductive path 112.

As further depicted in FIG. 2, the example conductive path 112 comprises a bridge portion 118. The bridge portion 118 of the conductive path 112 spans the separation gap 222 to electrically connect the input portion 224 and the output portion 226 of the conductive path 112. As described herein, the bridge portion 118 is removed from the interface surface of the lead-frame package comprising the conductive path 112.

As further depicted in FIG. 2, the input portion 224 and the output portion 226 of the conductive path 112 define a separation gap 222. The separation gap 222 separates the input portion 224 of the conductive path 112 from the output portion 226 of the conductive path 112, such that the electrical signal received at the input portion 224 is transmitted through the bridge portion 118 of the conductive path 112. Because of the reduced cross-sectional area of the bridge portion 118, the electrical signal is concentrated proximate an active region of an IC die (e.g., IC die 102 as described in relation to FIG. 1). Forcing the electrical signal through the reduced cross-sectional area of the bridge portion 118 enables more accurate measurements of the electrical properties of the electrical signal.

As further depicted in FIG. 2, the separation gap 222 is defined by the converging edges 220a, 220b, 220c, 220d of the input portion 224 and the output portion 226 of the conductive path 112. For example, on a first side of the bridge portion 118 the separation gap 222 is defined by the converging edge 220a of the input portion 224 and the converging edge 220c of the output portion 226. The converging edges 220a, 220c form a first converging portion 222a of the separation gap 222 that is wider proximate the periphery of the conductive path 112 (e.g., lead frame) and relatively narrower proximate the bridge portion 118 of the conductive path 112. As depicted in FIG. 2, the converging edge 220a and the converging edge 220c linearly converge, forming a tapered first converging portion 222a of the separation gap 222.

As further depicted in FIG. 2, on a second side of the bridge portion 118 the separation gap 222 is defined by the converging edge 220b of the input portion 224 and the converging edge 220d of the output portion 226. The converging edges 220b, 220d form a second converging portion 222b of the separation gap 222 that is wider proximate the periphery of the conductive path 112 (e.g., lead frame) and relatively narrower proximate the bridge portion 118 of the conductive path 112. As depicted in FIG. 2, the converging edge 220b and the converging edge 220d linearly converge, forming a tapered second converging portion 222b of the separation gap 222.

The tapered separation gap 222 enables molding material (e.g., molding material 110 as described in relation to FIG. 1) to completely fill the separation gap 222, including the gap between the bridge portion 118 and the interface surface of the lead-frame package. The molding material in the separation gap 222 provides electrical insulation and protection to the electrical components of the conductive path 112. Thus, the conductive path may operate more reliably and efficiently. In addition, the tapered separation gap 222 converging toward the bridge portion 118 of the conductive path may decrease temperature hot spots at the entrance to and the exit from the bridge portion 118 of the conductive path 112.

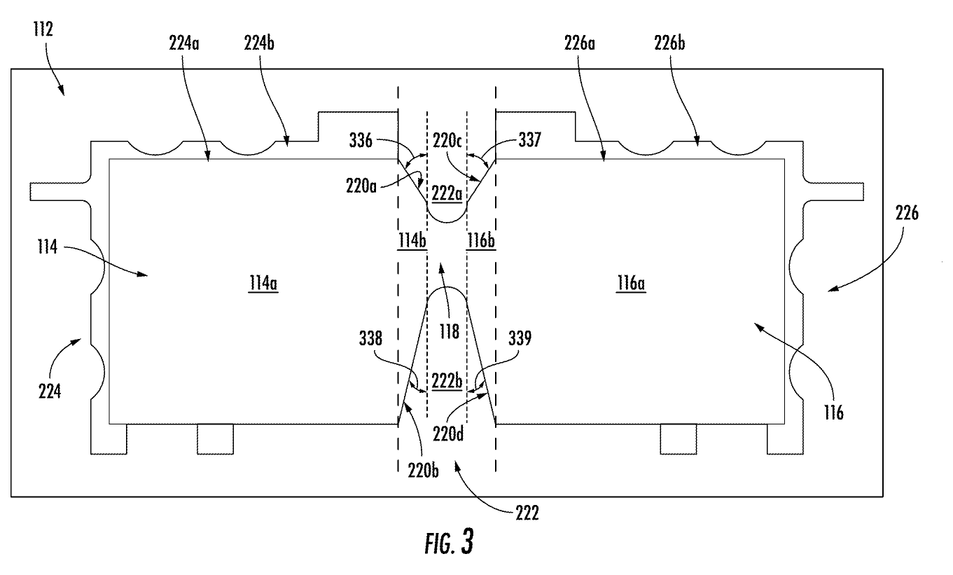

Referring now to FIG. 3, a bottom view an example conductive path 112 is depicted. As depicted in FIG. 3, the example conductive path 112 includes an input portion 224 and an output portion 226 connected by a bridge portion 118. The input portion 224 and output portion 226 are separated by and define a separation gap 222. The input portion 224 of the conductive path 112 and the output portion 226 of the conductive path 112 each comprise a set of converging edges 220a, 220b, 220c, 220d forming a converging (e.g., V-shaped) separation gap 222.

As further depicted in FIG. 3, the input portion 224 comprises a first layer 224a and a second layer 224b. The first layer 224a of the input portion 224 comprises at least an input pad 114 forming at least a portion of the interface surface of a lead-frame package. The second layer 224b is set back or removed from the interface surface such that it is co-planar with the bridge portion 118 of the conductive path 112. In some embodiments, the second layer 224b comprises a greater surface area than the input pad 114.

As further depicted in FIG. 3, the output portion 226 comprises a first layer 226a and a second layer 226b. The first layer 226a of the output portion 226 comprises at least an output pad 116 forming at least a portion of the interface surface of the lead-frame package. The second layer 226b is set back or removed from the interface surface such that it is co-planar with the bridge portion 118 of the conductive path 112 and the second layer 224b of the input portion 224. In some embodiments, the second layer 226b comprises a greater surface area than the output pad 116.

As further depicted in FIG. 3, the input pad 114 of the example conductive path 112 includes an input rectangular portion 114a and an input trapezoidal portion 114b. The input rectangular portion 114a comprises any conductive portion of the input pad 114 at the interface surface having four sides intersecting at four right angles. The input trapezoidal portion 114b comprises any conductive portion of the input pad 114 at the interface surface having four sides wherein one pair of sides is parallel and the other pair of sides is not. The non-parallel sides of the input trapezoidal portion 114b are defined by the converging edge 220a and the converging edge 220b.

The first converging edge angle 336 defines at least part of the angle of convergence of the first converging portion 222a of the separation gap 222. In some embodiments, the first converging edge angle 336 is between 4 degrees and 45 degrees; more preferably between 10 degrees and 35 degrees; most preferably between 15 degrees and 30 degrees. The selection of the first converging edge angle 336 presents a trade-off between size of the input pad 114 and the ease with which molding material may fill the separation gap 222. The wider the first converging edge angle 336, the easier it is to fill the separation gap 222 with molding material, but the wider the input pad 114 becomes. The narrower the first converging edge angle 336, the harder it is to fill the separation gap 222 with molding material, but the width of the input pad 114 may be reduced.

The second converging edge angle 338 defines at least part of the angle of convergence of the second converging portion 222b of the separation gap 222. In some embodiments, the second converging edge angle 338 is between 4 degrees and 45 degrees; more preferably between 10 degrees and 35 degrees; most preferably between 15 degrees and 30 degrees. The selection of the second converging edge angle 338 presents a trade-off between size of the input pad 114 and the ease with which molding material may fill the separation gap 222. The wider the second converging edge angle 338, the easier it is to fill the separation gap 222 with molding material, but the wider the input pad 114 becomes. The narrower the second converging edge angle 338, the harder it is to fill the separation gap 222 with molding material, but the width of the input pad 114 may be reduced.

As further depicted in FIG. 3, the output pad 116 of the example conductive path 112 includes an output rectangular portion 116a and an output trapezoidal portion 116b. The output rectangular portion 116a comprises any conductive portion of the output pad 116 at the interface surface having four sides intersecting at four right angles. The output trapezoidal portion 116b comprises any conductive portion of the output pad 116 at the interface surface having four sides wherein one pair of sides is parallel and the other pair of sides is not. The non-parallel sides of the output trapezoidal portion 116b are defined by the converging edge 220c and the converging edge 220d.

The first converging edge angle 337 defines at least part of the angle of convergence of the first converging portion 222a of the separation gap 222. In some embodiments, the first converging edge angle 337 is between 4 degrees and 45 degrees; more preferably between 10 degrees and 35 degrees; most preferably between 15 degrees and 30 degrees. The selection of the first converging edge angle 337 presents a trade-off between size of the output pad 116 and the ease with which molding material may fill the separation gap 222. The wider the first converging edge angle 337, the easier it is to fill the separation gap 222 with molding material, but the wider the output pad 116 becomes. The narrower the first converging edge angle 337, the harder it is to fill the separation gap 222 with molding material, but the width of the output pad 116 may be reduced.

The second converging edge angle 339 defines at least part of the angle of convergence of the second converging portion 222b of the separation gap 222. In some embodiments, the second converging edge angle 339 is between 4 degrees and 45 degrees; more preferably between 10 degrees and 35 degrees; most preferably between 15 degrees and 30 degrees. The selection of the second converging edge angle 339 presents a trade-off between size of the output pad 116 and the ease with which molding material may fill the separation gap 222. The wider the second converging edge angle 339, the easier it is to fill the separation gap 222 with molding material, but the wider the output pad 116 becomes. The narrower the second converging edge angle 339, the harder it is to fill the separation gap 222 with molding material, but the width of the output pad 116 may be reduced.

As depicted in FIG. 3, in some embodiments, the converging edge 220a and the converging edge 220b may be mirror images of the converging edge 220c and the converging edge 220d.

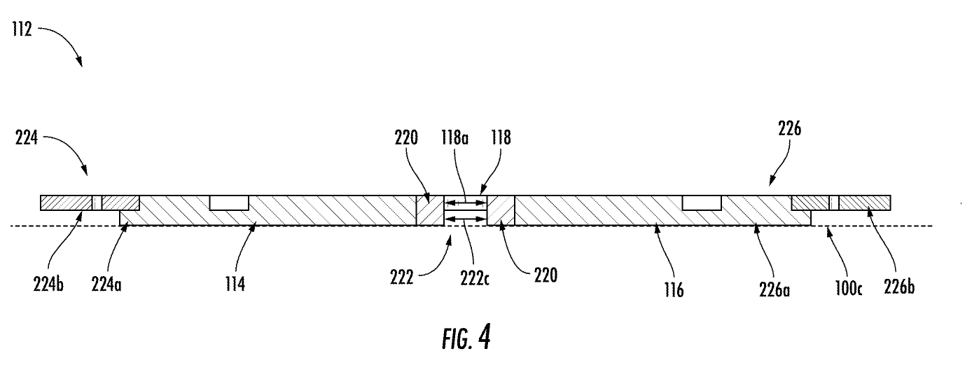

Referring now to FIG. 4, a side view of an example conductive path 112 in a lead-frame package is provided. As depicted in FIG. 4, the example conductive path 112 includes an input portion 224 and an output portion 226 connected by a bridge portion 118. The input portion 224 and output portion 226 are separated by and define a converging separation gap 222 as defined by the converging edges 220 of the input portion 224 and the output portion 226.

As further depicted in FIG. 4, the input portion 224 comprises a first layer 224a and a second layer 224b. The first layer 224a of the input portion 224 comprises at least an input pad 114 forming at least a portion of the interface surface 100c of a lead-frame package. The second layer 224b is set back or removed from the interface surface 100c such that it is co-planar with the bridge portion 118 of the conductive path 112. In some embodiments, the second layer 224b comprises a greater surface area than the input pad 114.

As further depicted in FIG. 4, the output portion 226 comprises a first layer 226a and a second layer 226b. The first layer 226a of the output portion 226 comprises at least an output pad 116 forming at least a portion of the interface surface 100c of the lead-frame package. The second layer 226b is set back or removed from the interface surface 100c such that it is co-planar with the bridge portion 118 of the conductive path 112 and the second layer 224b of the input portion 224. In some embodiments, the second layer 226b comprises a greater surface area than the output pad 116.

As further depicted in FIG. 4, the bridge portion 118 is removed from the interface surface 100c, such that a gap is formed between the bridge portion 118 and the interface surface 100c between the input pad 114 of the first layer 224a of the input portion 224 and the output pad 116 of the first layer 226a of the output portion 226. In addition, as further depicted in FIG. 4, the input pad 114 and the output pad are directly adjacent to the narrowed bridge portion 118, such that the separation gap distance 222c between the first layer 224a of the input portion 224 and the first layer 226a of the output portion 226 is equal to the bridge portion length 118a. In some embodiments, the bridge portion length 118a may be between 0.45 millimeters and 0.65 millimeters; more preferably between 0.475 millimeters and 0.625 millimeters; most preferably between 0.5 millimeters and 0.6 millimeters.

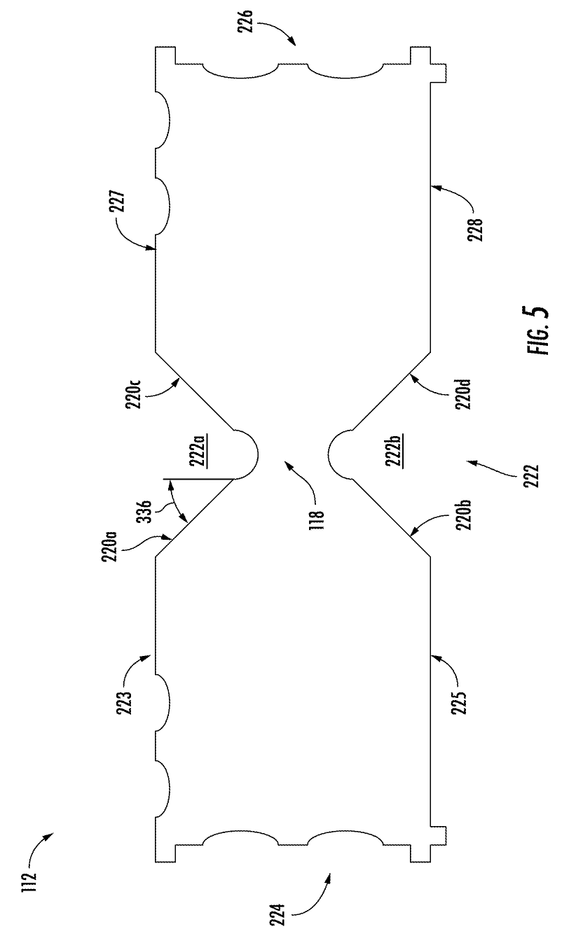

Referring now to FIG. 5, a top view of an example conductive path 112 (e.g., lead frame) is depicted. As depicted in FIG. 5, the example conductive path 112 includes an input portion 224 and an output portion 226 connected by a bridge portion 118. The input portion 224 and output portion 226 are separated by and define a separation gap 222. The input portion 224 of the conductive path 112 and the output portion 226 of the conductive path 112 each comprise a set of converging edges 220a, 220b, 220c, 220d forming a converging (e.g., V-shaped) separation gap 222.

As depicted in FIG. 5, the example conductive path 112 includes an input portion 224. Although not depicted in FIG. 5, the input portion 224 comprises an input pad (e.g., input pad 114). Thus, an electrical signal may be received at the input portion 224, for example, from an electrical system.

As further depicted in FIG. 5, the input portion 224 comprises a first converging edge 220a defining a portion of the separation gap 222 between a first edge 223 of the input portion 224 and the bridge portion 118 of the conductive path 112. In addition, the input portion 224 comprises a second converging edge 220b defining a portion of the separation gap 222 between a second edge 225 of the input portion 224 and the bridge portion 118 of the conductive path 112.

As further depicted in FIG. 5, the example conductive path 112 includes an output portion 226. During operation, an electrical signal may be transmitted from the input portion 224, through the bridge portion 118, and out of the output portion 226, for example, back into an electrical system (e.g., system circuit board).

As further depicted in FIG. 5, the output portion 226 comprises a first converging edge 220c defining a portion of the separation gap 222 between a first edge 227 of the output portion 226 and the bridge portion 118 of the conductive path 112. In addition, the output portion 226 comprises a second converging edge 220d defining a portion of the separation gap 222 between a second edge 228 of the output portion 226 and the bridge portion 118 of the conductive path 112.

As further depicted in FIG. 5, the example conductive path 112 comprises a bridge portion 118. The bridge portion 118 of the conductive path 112 spans the separation gap 222 to electrically connect the input portion 224 and the output portion 226 of the conductive path 112. The bridge portion 118 is removed from the interface surface of the lead-frame package comprising the conductive path 112.

As further depicted in FIG. 5, the input portion 224 and the output portion 226 of the conductive path 112 define a separation gap 222. The separation gap 222 separates the input portion 224 of the conductive path 112 from the output portion 226 of the conductive path 112, such that the electrical signal received at the input portion 224 is transmitted through the bridge portion 118 of the conductive path 112.

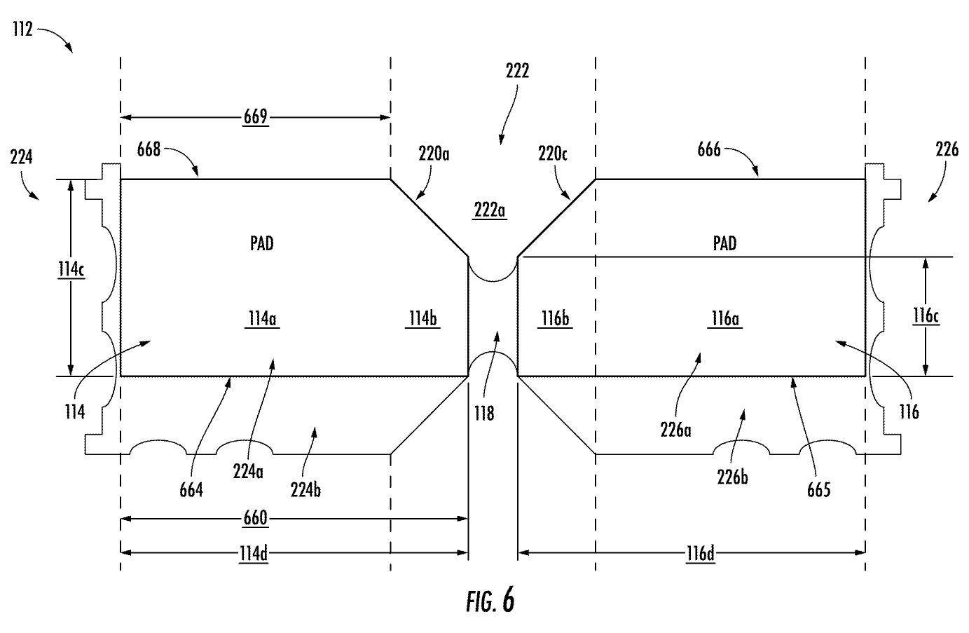

As further depicted in FIG. 5, the separation gap 222 is defined by the converging edges 220a, 220b, 220c, 220d of the input portion 224 and the output portion 226 of the conductive path 112. The first converging edge angle 336 defines at least part of the angle of convergence of the first converging portion 222a of the separation gap 222. As depicted in FIG. 5, the angle of convergence of each of the converging edges 220a, 220b, 220c, 220d, may be equivalent, for example, 45 degrees. Equivalent angles of conversion center the bridge portion across the height of the conductive path. In addition, each of the converging edges 220a, 220b, 220c, 220d are identical in length. Such a tapered separation gap 222 enables molding material to completely fill the separation gap 222, including the gap between the bridge portion 118 and the interface surface of the lead-frame package. As depicted in FIG. 6, the converging edges 220a, 220c continue through the first layer of the input portion 224 and the output portion 226, however, the converging edges 220b and 220d are only present on the second layer of the input portion 224 and the output portion 226.

Referring now to FIG. 6, a bottom view of an example conductive path 112 is depicted. As depicted in FIG. 6, the example conductive path 112 includes an input portion 224 and an output portion 226 connected by a bridge portion 118. The input portion 224 and output portion 226 are separated by and define a separation gap 222. The input pad 114 of the input portion 224 of the conductive path 112 and the output pad 116 of the output portion 226 of the conductive path 112 each comprise a converging edge 220a, 220c forming a converging (e.g., V-shaped) separation gap 222 in a converging portion 222a of the separation gap 222.

As further depicted in FIG. 6, the input portion 224 comprises a first layer 224a and a second layer 224b. The first layer 224a of the input portion 224 comprises at least an input pad 114 forming at least a portion of the interface surface of a lead-frame package. The second layer 224b is set back or removed from the interface surface such that it is co-planar with the bridge portion 118 of the conductive path 112.

As further depicted in FIG. 6, the output portion 226 comprises a first layer 226a and a second layer 226b. The first layer 226a of the output portion 226 comprises at least an output pad 116 forming at least a portion of the interface surface of the lead-frame package. The second layer 226b is set back or removed from the interface surface such that it is co-planar with the bridge portion 118 of the conductive path 112 and the second layer 224b of the input portion 224.

As further depicted in FIG. 6, the input pad 114 and the output pad 116 comprise a smaller cross-sectional area than the second layer 224b and the second layer 226b respectively. For example, as depicted in FIG. 6, the input pad 114 comprise a lead edge 664 comprising a lead edge length 660, and a pad edge 668 comprising a pad edge length 669.

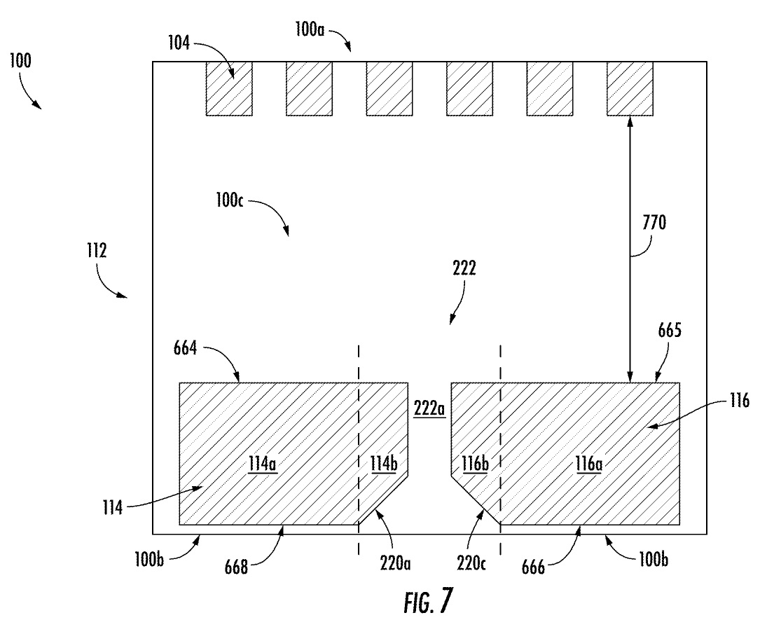

In the embodiment of FIG. 6, the lead edge 664 is closer to the bridge portion 118 compared to the pad edge 668. In addition, the lead edge 664 is also inset from the edge of the input portion 224 when compared to the second layer 224b. As such, the lead edge length 660 is greater than the pad edge length 669. In some embodiments, the lead edge length 660 is between 0.1 and 1.0 millimeters greater than the pad edge length 669; more preferably between 0.2 and 0.9 millimeters greater than the pad edge length 669; most preferably between 0.3 and 0.85 millimeters greater than the pad edge length 669. Moving the lead edge 664 of the input pad 114 closer to the bridge portion 118 enables a greater distance between the exposed lead edge 664 and the exposed leads of the lead-frame package, as further described in relation to FIG. 7.

Similarly, the output pad 116 comprises a lead edge 665 comprising a lead edge length, and a pad edge 666 comprising a pad edge length. In the embodiment of FIG. 6, the lead edge 665 is closer to the bridge portion 118 compared to the pad edge 666. In addition, the lead edge 665 is also inset from the edge of the output portion 226 when compared to the second layer 226b. As such, the lead edge length is greater than the pad edge length.

As further depicted in FIG. 6, the input pad 114 of the example conductive path 112 includes an input rectangular portion 114a and an input trapezoidal portion 114b. The input trapezoidal portion 114b comprises a single converging edge 220a. Thus, the converging portion 222a of the separation gap 222 converges linearly, while the separation gap on the first layer ends at the bridge portion 118 opposite the converging portion 222a.

As further depicted in FIG. 6, the output pad 116 of the example conductive path 112 includes an output rectangular portion 116a and an output trapezoidal portion 116b. The output trapezoidal portion 116b comprises a single converging edge 220c. As depicted in FIG. 6, in some embodiments, the converging edge 220a and the converging edge 220c may be mirror images of each other.

As depicted in FIG. 6, the input pad 114 comprises an input pad width 114d, and an input pad height 114c. In some embodiments, the input pad width 114d is between 2.75 millimeters and 3.75 millimeters; more preferably between 2.80 millimeters and 3.5 millimeters; most preferably between 2.90 millimeters and 3.25 millimeters. In some embodiments, the input pad height 114c is between 2.00 millimeters and 2.25 millimeters; more preferably between 2.05 millimeters and 2.20 millimeters; most preferably between 2.05 millimeters and 2.10 millimeters.

As further depicted in FIG. 6, the output pad 116 comprises an output pad width 116d, and an output pad height 116c. In some embodiments, the output pad width 116d is between 2.75 millimeters and 3.75 millimeters; more preferably between 2.80 millimeters and 3.5 millimeters; most preferably between 2.90 millimeters and 3.25 millimeters. In some embodiments, the output pad height 116c is between 2.00 millimeters and 2.25 millimeters; more preferably between 2.05 millimeters and 2.20 millimeters; most preferably between 2.05 millimeters and 2.10 millimeters.

Referring now to FIG. 7, an example lead-frame package 100 comprising a plurality of leads 104, and a conductive path 112 in accordance with an example embodiment of the present disclosure is provided. As depicted in FIG. 7, the lead-frame package 100 defines a lead package side 100a proximate the plurality of leads 104, an IC package side 100b proximate the input pad 114 and the output pad 116 of the conductive path 112, and an interface surface 100c exposing the conductive leads 104, the input pad 114, and the output pad 116.

As further depicted in FIG. 7, the input pad 114 and the output pad 116 both comprise a rectangular portion (e.g., rectangular portion 114a, 116a) and a trapezoidal portion (e.g., trapezoidal portion 114b, 116b), wherein the trapezoidal portion defines the separation gap 222 between the input pad 114 and the output pad 116. As depicted in FIG. 7, the converging edges 220a, 220c of the trapezoidal portions 114b, 116b form a converging portion 222a of the separation gap 222. The converging portion 222a enables molding material to complete fill the separation gap 222 such that the bridge portion which is set back from the interface surface 100c is not exposed at the interface surface 100c once the molding material is formed. In addition, the converging portion 222a of the separation gap further dissipates heat across the input pad 114 and output pad 116 respectively.

As further depicted in FIG. 7, the input pad 114 and the output pad 116 each comprise a lead edge 664, 665 proximate the leads 104 and a pad edge 666, 668 proximate the IC package side 100b of the lead-frame package 100. The depicted input pad 114 is formed such that the lead edge 664 is positioned closer to the bridge portion (not shown in FIG. 7) relative to the pad edge 668. In addition, the separation gap 222 proximate the lead edge 664 is not tapered. Thus, the length of the lead edge 664 of the input pad 114 is greater than the length of the pad edge 668 of the input pad 114. The geometry of the input pad 114 enables a greater distance (e.g., lead-pad distance 770) between the plurality of leads 104 and the exposed portion of the input pad 114.

The depicted output pad 116 is formed such that the lead edge 665 is positioned closer to the bridge portion (not shown in FIG. 7) relative to the pad edge 666. In addition, the separation gap 222 proximate the lead edge 665 is not tapered. Thus, the length of the lead edge 665 of the output pad 116 is greater than the length of the pad edge 666 of the output pad 116. The geometry of the output pad 116 enables a greater distance (e.g., lead-pad distance 770) between the plurality of leads 104 and the exposed portion of the output pad 116.

In addition, forming the input pad 114 and the output pad 116 in this way enables a larger surface area of the input pad 114 and the output pad 116, while still providing a converging portion 222a of the separation gap 222 enabling the separation gap 222 to easily fill with molding material. The larger surface area of the input pad 114 and the output pad 116 provide better dissipation of heat during operation.

As further depicted in FIG. 7, the lead-frame package 100 defines a lead-pad distance 770. The lead-pad distance 770 is the shortest distance between an exposed portion the plurality of leads 104 and an input pad 114 or output pad 116 of the conductive path 112. In some embodiments, a minimum lead-pad distance 770 may be specified by a standard. For example, in some embodiments, the lead-pad distance 770 must be greater than 3.5 millimeters. Moving the pad edge 668 of the input pad 114 and the pad edge 666 of the output pad 116 relatively closer to the bridge portion of the conductive path 112 as depicted in FIG. 7, may enable the minimum lead-pad distance 770 to be maintained. In some embodiments, the minimum lead-pad distance may be determined by the creepage phenomenon. Creepage is the unintended and undesirable movement of electrical current along the surface of an insulating material. Thus, the lead-pad distance 770 may be dependent on various parameters of the lead-frame package 100, including voltage characteristics. Using a lead-pad distance 770 of 3.5 millimeters as an example, the lead-frame package 100 may support an electrical signal of 2500 volts peak overvoltage class II, up to 300 volts rms.

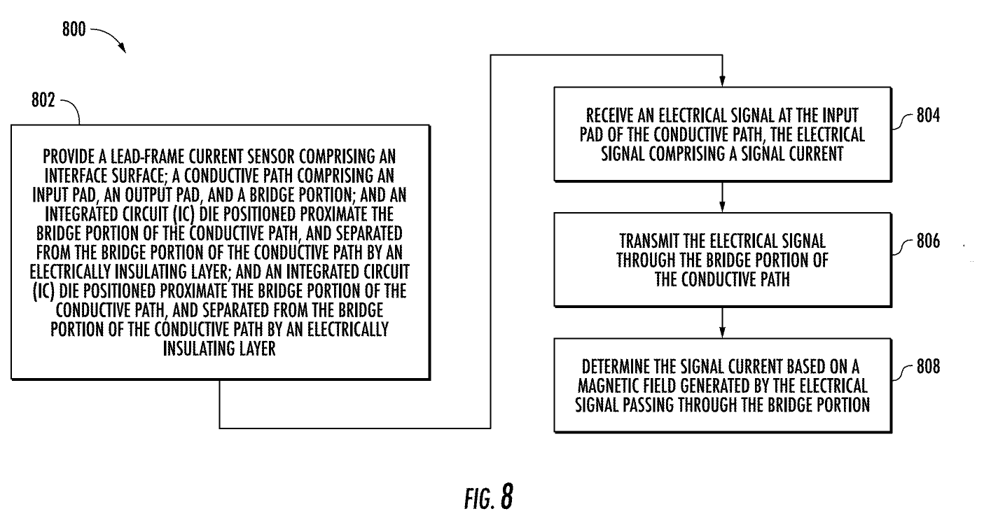

Referring now to FIG. 8, a flow chart of an example process 800 for determining a signal current associated with an electrical signal is depicted. At block 802 a lead-frame current sensor (e.g., lead-frame package 100) is provided. The lead-frame current sensor comprising an interface surface (e.g., interface surface 100c), a conductive path (e.g., conductive path 112), and an integrated circuit die (e.g., IC die 102). The conductive path includes an input pad (e.g., input pad 114) forming at least a first portion of the interface surface and an output pad (e.g., output pad 116) forming at least a second portion of the interface surface. A separation gap (e.g., separation gap 222) is defined between the input pad and the output pad. The conductive path further includes a bridge portion (e.g., bridge portion 118) electrically connecting the input pad to the output pad, wherein the bridge portion is removed from the interface surface. In addition, the separation gap is tapered such that the separation gap linearly converges toward the bridge portion electrically connecting the input pad and the output pad. The integrated circuit (IC) die positioned proximate the bridge portion of the conductive path, and separated from the bridge portion of the conductive path by an electrically insulating layer.

In some embodiments, the conductive portions of the lead-frame package (e.g., conductive path, leads) may be formed by stamping or chemically etching a conductive material. The IC die may then be positioned on the electrically insulating layer such that the active region of the IC die is positioned proximate the bridge portion of the conductive path. By positioning the active portion of the IC die proximate the bridge portion of the conductive path, the IC die may more accurately measure the signal current of the electrical signal transmitted through the conductive path. One or more bond wires may be attached between the IC die and the plurality of leads 104. Finally, a molding material may be formed around the electrical components of the lead-frame current sensor.

At block 804, the electrical signal is received at the input pad of the conductive path, the electrical signal comprising the signal current. The electrical signal may be any signal utilized in an electrical system comprising the lead-frame current sensor. For example, the electrical signal may be a motor control signal wherein the speed of the motor is correlated to the signal current of the electrical signal.

At block 806, the electrical signal is transmitted through the bridge portion of the conductive path. By transmitting the electrical signal through the narrow bridge portion of the conductive path, the current is concentrated in an area near the active portion of the IC die. Concentrating the current of the electrical signal near the active portion of the IC die enables the IC die to more accurately measure the magnetic field generated by the electrical signal.

At block 808, the signal current is determined based on the magnetic field generated by the electrical signal passing through the bridge portion. In some embodiments, the IC die may be configured to measure the magnetic field of the electrical signal and determine the current based on the magnetic field, for example, utilizing the Hall effect.

While this detailed description has set forth some embodiments of the present invention, the appended claims cover other embodiments of the present invention which differ from the described embodiments according to various modifications and improvements. For example, one skilled in the art may recognize that such principles may be applied to any lead-frame package receiving an electrical signal for purposes of determining one or more electrical properties.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A lead-frame package comprising:
an interface surface; and
a conductive path configured to receive an electrical signal comprising a signal current, the conductive path comprising:
an input pad forming at least a first portion of the interface surface;
an output pad forming at least a second portion of the interface surface,
wherein a separation gap is defined between the input pad and the output pad; and
a bridge portion electrically connecting the input pad to the output pad, wherein the bridge portion is removed from the interface surface,
wherein the separation gap is tapered such that the separation gap linearly converges toward the bridge portion electrically connecting the input pad and the output pad.

2. The lead-frame package of claim 1, further comprising:
a lead, wherein a portion of the lead is exposed at the interface surface proximate a lead package side of the lead-frame package.

3. The lead-frame package of claim 2, the input pad further comprising:
a lead edge comprising a lead edge length proximate the lead; and
a pad edge comprising a pad edge length opposite the lead edge.

4. The lead-frame package of claim 3, wherein the lead edge length is less than the pad edge length.

5. The lead-frame package of claim 3, wherein the pad edge is closer to the bridge portion than the lead edge.

6. The lead-frame package of claim 3, wherein a lead-pad distance defining a distance between the lead and the lead edge of the input pad is greater than a minimum lead-pad distance.

7. The lead-frame package of claim 6, wherein the minimum lead-pad distance is 3.5 millimeters.

8. The lead-frame package of claim 1, the input pad further comprising:
a gap edge adjacent to the separation gap defined between the input pad and the output pad; and
a first converging edge adjacent to the gap edge, wherein the first converging edge comprises a first converging edge angle relative to the gap edge;
wherein the first converging edge angle is greater than four degrees and less than forty-five degrees.

9. The lead-frame package of claim 8, the input pad further comprising:
a second converging edge adjacent to the gap edge opposite the first converging edge, wherein the second converging edge comprises a second converging edge angle relative to the gap edge;
wherein the second converging edge angle is greater than four degrees and less than forty-five degrees.

10. The lead-frame package of claim 1, the input pad comprising:
a first input pad layer forming the first portion of the interface surface; and
a second input pad layer;
wherein a second cross-sectional area of the second input pad layer is greater than a first cross-sectional area of the first input pad layer.

11. The lead-frame package of claim 10, wherein the bridge portion further comprises a bridge portion length, and wherein the separation gap proximate the bridge portion at the first input pad layer is equivalent to the bridge portion length.

12. The lead-frame package of claim 11, wherein the bridge portion length is greater than 0.5 millimeters and less than 0.6 millimeters.

13. The lead-frame package of claim 1, the input pad comprising:
an input rectangular portion; and
an input trapezoidal portion;
wherein the input trapezoidal portion defines the separation gap.

14. The lead-frame package of claim 1, the output pad comprising:
an output rectangular portion; and
an output trapezoidal portion;
wherein the output trapezoidal portion defines the defines the separation gap.

15. The lead-frame package of claim 1, wherein the input pad comprises an input pad width, and wherein the input pad width is greater than 2.75 millimeters.

16. The lead-frame package of claim 1, wherein the input pad comprises an input pad height, and wherein the input pad height is greater than 2 millimeters.

17. The lead-frame package of claim 1, wherein the lead-frame package is configured to measure the signal current at an integrated circuit (IC) die.

18. A lead-frame current sensor comprising:
an interface surface;
a conductive path configured to receive an electrical signal comprising a signal current, the conductive path comprising:
an input pad forming at least a first portion of the interface surface;
an output pad forming at least a second portion of the interface surface,
wherein a separation gap is defined between the input pad and the output pad; and
a bridge portion electrically connecting the input pad to the output pad, wherein the bridge portion is removed from the interface surface,
wherein the separation gap is tapered such that the separation gap linearly converges toward the bridge portion electrically connecting the input pad and the output pad; and
an integrated circuit (IC) die positioned proximate the bridge portion of the conductive path, and separated from the bridge portion of the conductive path by an electrically insulating layer.

19. The lead-frame current sensor of claim 18, the input pad comprising:
an input rectangular portion, and
an input trapezoidal portion;
the output pad comprising:
an output rectangular portion, and
an output trapezoidal portion;
wherein the input trapezoidal portion and the output trapezoidal portion define the separation gap.

20. A method for determining a signal current associated with an electrical signal, the method comprising:
providing a lead-frame current sensor comprising:
an interface surface;
a conductive path comprising:
an input pad forming at least a first portion of the interface surface;
an output pad forming at least a second portion of the interface surface,
wherein a separation gap is defined between the input pad and the output pad; and
a bridge portion electrically connecting the input pad to the output pad, wherein the bridge portion is removed from the interface surface,
wherein the separation gap is tapered such that the separation gap linearly converges toward the bridge portion electrically connecting the input pad and the output pad; and
an integrated circuit (IC) die positioned proximate the bridge portion of the conductive path, and separated from the bridge portion of the conductive path by an electrically insulating layer;
receiving the electrical signal at the input pad of the conductive path, the electrical signal comprising the signal current;
transmitting the electrical signal through the bridge portion of the conductive path; and
determining the signal current based on a magnetic field generated by the electrical signal passing through the bridge portion.
